(19) United States
(12) Patent Application Publication
(10) Pub. No.: US 2008/0090180 A1
(43) Pub. Date: Apr. 17, 2008

(54) METHOD OF FABRICATING SEMICONDUCTOR DEVICE

(75) Inventors: Sang Sik KIM, Seoul (KR); Meng An JUNG, Seoul (KR); Duk Soo KIM, Seoul (KR); Jun Han YUN, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/872,514

(22) Filed: Oct. 15, 2007

(30) Foreign Application Priority Data
Oct. 16, 2006 (KR) 10-2006-0100168

(51) Int. Cl. G03F 7/20

(52) U.S. Cl. 430/311

(57) ABSTRACT

A semiconductor fabrication method may include depositing hexamethyldisilazane (HMDS) on a wafer surface, cooling the wafer and coating the wafer surface with a first photoresist, heating the wafer on which the first photoresist has been coated to induce a silylation reaction, cooling the wafer, and developing and removing the first photoresist. Adhesion between the wafer's surface and a subsequently applied photoresist may thus be enhanced. Accordingly, manufacturing time can be saved and productivity can be improved by simplifying the fabrication process and preventing waste of materials.

### CROSS-REFERENCE TO RELATED APPLICATION

This application claims priority to Korean Application No. 10-2006-0100168, filed on Oct. 16, 2006, which is incorporated herein by reference in its entirety.

### BACKGROUND

1. Field of the Invention

The present invention relates to a method of fabricating semiconductor devices.

2. Background of the Invention

In a photolithography process used in a conventional method of fabricating a semiconductor device, in order to enhance an adhesion between a photoresist and a wafer, the following steps as shown in FIG. 1 are typically performed: depositing hexamethyldisilazane (hereinafter, referred to as “HMDS”) on a wafer surface; cooling the wafer; coating a photoresist thereon and heating the wafer; cooling the wafer again; and then exposing the photoresist coated on the wafer with an exposure apparatus and developing the photoresist.

However, adequate adhesion is not always achieved. Therefore, defective photoresist patterns must frequently be removed. The same tasks must then be repeated, resulting in higher material costs and manufacturing delays.

### SUMMARY OF SOME EXAMPLE EMBODIMENTS

In general, example embodiments of the invention relate to a method of fabricating a semiconductor device capable of saving manufacturing time and improving productivity by suppressing an increase in the processing time and a waste of materials caused by defective photoresist patterns.

In accordance with an example embodiment, there is provided a method of fabricating a semiconductor device, including the steps of depositing HMDS on a wafer surface, cooling the wafer and coating the wafer surface with a first photoresist, heating the wafer on which the first photoresist has been coated to induce a silylation reaction, cooling the wafer, and developing and removing the first photoresist.

The HMDS can be deposited on the wafer in a temperature range of 80 to 150 degrees Celsius for 20 to 120 seconds.

The first photoresist can include a negative-based photoresist or a thermosetting photoresist.

The first photoresist can be heated in a temperature range of 80 to 120 degrees Celsius for 30 to 200 seconds.

The step of developing and removing the first photoresist can be performed in a temperature range of 100 to 250 degrees Celsius for 30 to 300 seconds.

The method can further include the steps of developing and removing the first photoresist and then coating the wafer surface with a second photoresist. The second photoresist may then be exposed and developed.

### BRIEF DESCRIPTION OF THE DRAWINGS

Aspects of example embodiments of the invention will become apparent from the following description of example embodiments given in conjunction with the accompanying drawings, in which:

FIG. 1 is a flowchart illustrating a conventional method of fabricating semiconductor devices;

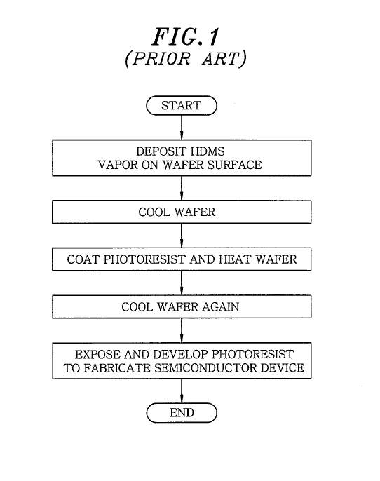

FIG. 2 is a flowchart illustrating a method of fabricating semiconductor devices in accordance with an embodiment of the present invention;

FIG. 3 is a view illustrating a hydrophilization reaction between HMDS and the surface of a wafer, employed in the prior art; and

FIG. 4 is a Scanning Electron Microscope (SEM) image of a wafer surface after a first photoresist is developed in accordance with an embodiment of the present invention.

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

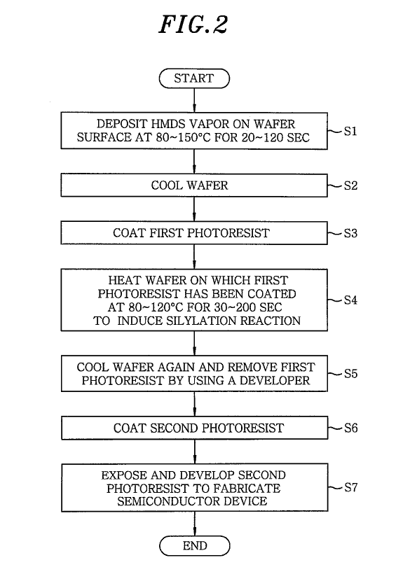

FIG. 2 is a flowchart illustrating a method of fabricating semiconductor devices in accordance with an embodiment of the present invention.

HMDS is first deposited on a wafer surface (Si). HMDS is a material for increasing hydrophobicity of the wafer. HMDS may be deposited in a vapor state before coating the wafer with a first photoresist in order to improve adherence between the first photoresist and the wafer. HMDS may be deposited on the wafer in a temperature range of 80 to 150 degrees Celsius for 20 to 120 seconds. The deposition process may be performed, for example, when the temperature of a wafer plate on which the wafer is placed is 130 degrees Celsius.

The wafer expands due to heating during the HMDS deposition step, which may degrade the uniformity of the wafer when coating the first photoresist. Thus, the wafer may be cooled and the temperature of the wafer controlled in order to improve the uniformity (S2). The cooling temperature may vary depending on the type and thickness of the first photoresist. For example, the cooling process can be performed in a temperature range of 21 to 23 degrees Celsius for 60 seconds.

The first photoresist is then coated on the wafer (S3). The first photoresist may include a negative photoresist or thermosetting-based resist that can be removed with a developer after inducing a silylation reaction in a subsequent process.

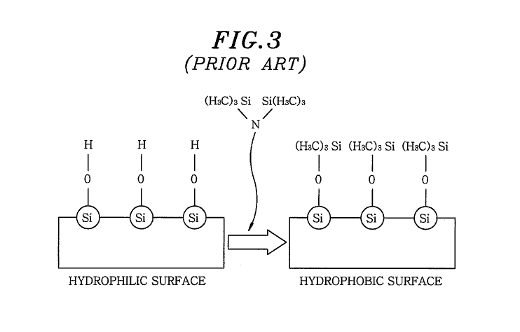

Thereafter, as shown in FIG. 3, the wafer on which the first photoresist is coated may be heated (S4) which induces a hydrophilization reaction between the HMDS deposited in S1 and the wafer surface. A hydrophilization reaction is a reaction in which a SiOH group on the wafer surface reacts to organosilane, thus reducing hydrophilicity and increasing hydrothermal stability. Materials used for the hydrophilization reaction can include chlorosilanes, alkoxysilanes, silylamines, HMDS and so on. Chlorosilanes and alkoxysilanes form a polymer through reaction with moisture when moisture on a solvent or a mezzo material surface that performs the hydrophilization reaction is not sufficiently removed. The moisture can eventually be eluted since part of the mezzo material surface is simply adsorbed. Thus, chlorosilanes and alkoxysilanes may be preferred over HMDS or silylamines.

Further heating is performed in S4 to induce a silylation reaction between the first photoresist and HMDS. A silyation reaction is a chemical reaction between HMDS and photoresist material that generates siloxane (Si—O—Si) bonding, by which an adhesion between a wafer surface and a photoresist can be enhanced. To induce the silylation reaction, the wafer on which the first negative or thermosetting-based photoresist has been coated may be heated in a temperature range of 80 to 120 degrees Celsius for 30 to 200 seconds.

Next, in order to improve the uniformity of the heated wafer, the wafer may be cooled in a temperature range of 21 to 23 degrees Celsius, and the first photoresist may be removed by using a developer (S5). The step of developing and removing the first photoresist can be performed in a temperature range of 100 to 250 degrees Celsius for 30 to 300 seconds.

A second photoresist may then be coated on the wafer (S6). The second photoresist may be a typical photoresist, as opposed to the first photoresist, which is adapted for removal after the silylation reaction. Thereafter, the second photoresist may be exposed and developed through typical processes to complete fabrication of a semiconductor device (S7).

The above method of fabricating the semiconductor device described above according to an embodiment of the present invention may be summarized as follows.

After HMDS is deposited on a wafer surface, the wafer surface may be coated with a first negative or thermosetting-based photoresist. The wafer may then be processed (e.g., by heating) to induce a hydrophilization reaction of a silane of the wafer surface and the photoresist, converting a hydrophilic wafer surface into a hydrophobic wafer surface (refer to FIG. 3). In order to induce the silylation reaction between the first photoresist and HMDS, the wafer on which the negative or thermosetting-based photoresist has been coated may be heated in the temperature range of 80 to 120 degrees Celsius for 30 to 200 seconds.

Consequently, when the wafer surface is coated with a common second photoresist, a condensation reaction between the second photoresist and a methoxy or etoxy radical on the wafer surface is induced, leading to Si—O—Si coupling. Thus, silane is crosslinked to become a gel.

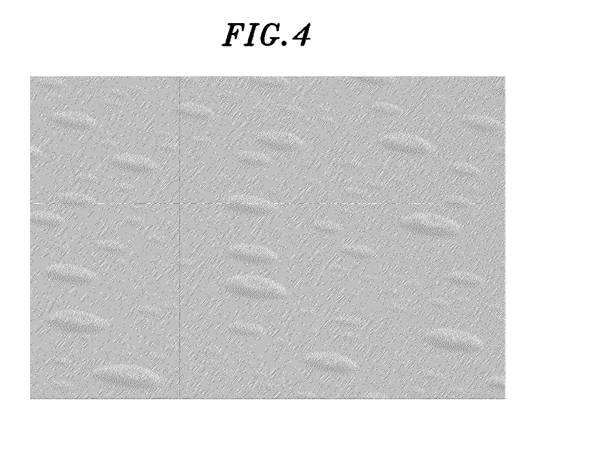

FIG. 4 is a Scanning Electron Microscope (SEM) image of the wafer surface after the first photoresist is developed. As shown in FIG. 4, the wafer surface is generally rough at this stage due to the surface's hydrophobicity and the silane gel formed thereon. Therefore, the surface area of the wafer that is brought into contact with the second photoresist may be increased, thereby preventing separation of the second photoresist pattern from the wafer surface.

Therefore, in accordance with this example embodiment, manufacturing time can be saved and productivity can be improved by simplifying the fabrication process and preventing waste of materials.

While the invention has been shown and described with respect to this example embodiment, it will be understood by those skilled in the art that various changes and modifications may be made without departing from the spirit and scope of the invention as defined in the following claims.

What is claimed is:

1. A method of fabricating a semiconductor device, comprising the steps of:
depositing hexamethyldisilazane (HMDS) on a wafer surface;
cooling the wafer and coating the wafer surface with a first photoresist;
heating the wafer on which the first photoresist has been coated to induce a silylation reaction;
cooling the wafer; and
developing and removing the first photoresist.

2. The method of claim 1, wherein the HMDS is deposited on the wafer in a temperature range of 80 to 150 degrees Celsius for 20 to 120 seconds.

3. The method of claim 1, wherein the first photoresist includes a negative-based photoresist or a thermosetting photoresist.

4. The method of claim 1, wherein the first photoresist is heated in a temperature range of 80 to 120 degrees Celsius for 30 to 200 seconds.

5. The method of claim 1, wherein the step of developing and removing the first photoresist is performed in a temperature range of 100 to 250 degrees Celsius for 30 to 300 seconds.

6. The method of claim 1, further comprising the steps of:
developing and removing the first photoresist and coating the wafer surface with a second photoresist; and
exposing and developing the second photoresist.
